(19) United States
(12) Patent Application Publication
(10) Pub. No.: US 2022/0132680 A1
(43) Pub. Date: Apr. 28, 2022

(54) SUPPORT FOR FLEXIBLE DISPLAY MODULE, DISPLAY MODULE AND DEVICE

(71) Applicants: CHENGDU BOE OPTOELECTRONICS TECHNOLOGY CO., LTD., Chengdu (CN); BOE TECHNOLOGY GROUP CO., LTD., Beijing (CN)

(72) Inventors: Shaokui Liu, Beijing (CN); Zhihui Wang, Beijing (CN); Danping Shen, Beijing (CN); Wei Zeng, Beijing (CN)

(73) Assignees: CHENGDU BOE OPTOELECTRONICS TECHNOLOGY CO., LTD., Chengdu (CN); BOE TECHNOLOGY GROUP CO., LTD., Beijing (CN)

(21) Appl. No.: 17/406,715

(22) Filed: Aug. 19, 2021

(30) Foreign Application Priority Data
Oct. 26, 2020 (CN) 202022408156.7

(51) Int. Cl. H05K 5/00

(52) U.S. Cl. CPC H05K 5/0017

(57) ABSTRACT

The disclosure provides a support for a flexible display module, a display module and a device. The support for the flexible display module comprises metal layers and supporting layers arranged with one above another, and is characterized in that each metal layer comprises non-patterned areas and patterned areas, the patterned area is a notch and/or a micro-hole etching area arranged on the metal layer, and a filling layer is arranged in the notch.

The disclosure claims priority to Chinese Patent Application No. 202022408156.7, entitled “Support for Flexible Display Module, Display Module and Device”, filed with the China National Intellectual Property Administration on Oct. 26, 2020, which is incorporated herein by reference in its entirety.

### TECHNICAL FIELD

The disclosure generally relates to the technical field of display equipment, in particular to a support for a flexible display module, a display module and a device.

### BACKGROUND

With the development of flexible display technology, people not only demand high resolutions, high contrasts, high screen ratios and other display effects of display devices, but also have diversified requirements for the appearance of display devices, such as special-shaped display panels and rollable display panels. The rollable display panel is a flexible display panel, and the trend of flexible display is foldable and rollable.

Flexible OLED displays are a flexible conceptual product developed for the rich display scenarios in the future. An OLED panel is characterized by a substrate made of an organic film material, a thin and flexible overall device structure, the ability to realize display within the thickness range of tens of microns, and high packaging reliability.

Based on various flexible application scenarios (folding, rolling, stretching, etc.) of flexible OLED displays, matching display modules, especially back support materials, should also be designed differently. In order to ensure that the flexible display can restore flatness after being bent for a while and improve the screen support performance in a planar state, a hard (especially metal) support chip has a wide application prospect because of its shape retention and stress dispersion in a bent state. End products are designed with different rolling radii and inward and outward folding features (display surfaces facing different directions), and a back support can meet different requirements for rolling ability through multi-layer patterned metal. In addition, through the design of different metal layer materials, the functional requirements of other areas can be taken into account.

### SUMMARY

The disclosure provides a support for a flexible display module, a display module and a device.

In a first aspect, the disclosure provides a support for a flexible display module, the support comprises metal layers and supporting layers arranged with one above another, each metal layer comprises non-patterned areas and patterned areas, the patterned area is a notch and/or a micro-hole etching area arranged on the metal layer, and a filling layer is arranged in the notch.

Optionally, the patterned area is strip-shaped, and at least one group of the patterned area is arranged on the metal layer.

Optionally, the patterned area comprises the notch and the micro-hole etching area which are arranged with one above the other, and the notch is located on the side of the patterned area close to the supporting layer.

Optionally, the number of metal layers is greater than or equal to 2.

Optionally, under the case that there are two metal layers, the supporting layers are arranged between the two metal layers.

Optionally, under the case that there are two metal layers, the metal layers are all provided with the patterned areas, and the patterned areas on two vertically adjacent metal layers are arranged in a staggered way.

Optionally, the shapes of etched holes in the micro-hole etching areas include one or more of round, square or other irregular shapes.

Optionally, the supporting layers are made of a polymer material.

Optionally, the filling layers are made of a polymer material.

In a second aspect, the disclosure provides a flexible display module, comprising a flexible display screen and the support for the flexible display module as described above, wherein the support is fixedly arranged on the flexible display screen through an adhesive layer.

Optionally, the flexible display screen comprises a flat area and a rolled-up area, the patterned areas are arranged on the metal layers corresponding to the rolled-up area, and at least one metal layer on the flat area is provided with the non-patterned area.

In a third aspect, the disclosure provides a display device comprising the support for the flexible display module as described above.

The aforesaid description is merely a brief summary of the technical solution of the disclosure. To allow those skilled in the art to gain a better understanding of the technical means of the disclosure to implement the disclosure according to the contents in the specification and to make the above and other purposes, features and advantages of the disclosure clearer, specific implementations of the disclosure are given below.

### BRIEF DESCRIPTION OF THE DRAWINGS

To more clearly explain the technical solutions of the embodiments of the disclosure or related arts, drawings for describing the embodiments of the disclosure or the related arts will be briefly introduced below. Obviously, the drawings in the following description only illustrate some embodiments of the disclosure, and those ordinarily skilled in the art can obtain other drawings according to the following ones without creative labor.

Other features, objects and advantages of the disclosure will become more apparent by reading the detailed description of non-limiting embodiments made with reference to the following drawings.

FIG. 1 is a structural diagram of a first support for a flexible display module provided by an embodiment of the disclosure;

FIG. 2 is a structural diagram of a second support for a flexible display module provided by an embodiment of the disclosure;

FIG. 3 is a structural diagram of a third support for a flexible display module provided by an embodiment of the disclosure;

FIG. 4 is a structural diagram of a fourth support for a flexible display module provided by an embodiment of the disclosure;

FIG. 5 is a structural diagram of a fifth support for a flexible display module provided by an embodiment of the disclosure;

FIG. 6 is a structural diagram of a sixth support for a flexible display module provided by an embodiment of the disclosure;

FIG. 7 is a structural diagram of a flexible display module provided by an embodiment of the disclosure in a rolled state;

FIG. 8 is a structural diagram of a flexible display module provided by an embodiment of the disclosure in a slide-rolled state;

FIG. 9 is a top view of a support for a flexible display module provided by an embodiment of the disclosure;

FIG. 10 is a cross section of a support for a flexible display module provided by an embodiment of the disclosure;

FIG. 11 is a structural diagram of etched holes with equal spacing provided by an embodiment of the disclosure; and

FIG. 12 is a structural diagram of progressively etched holes provided by an embodiment of the disclosure.

### DETAILED DESCRIPTION

The disclosure will be further described in detail with reference to the drawings and embodiments. It can be understood that the specific embodiments described herein are only used to explain related inventions, but not to limit the invention. It should also be noted that for convenience of description, only the parts related to the invention are shown in the drawings.

It should be noted that the embodiments in the disclosure and the features in the embodiments can be combined without conflict. Hereinafter, the disclosure will be described in detail with reference to the drawings and in combination with embodiments.

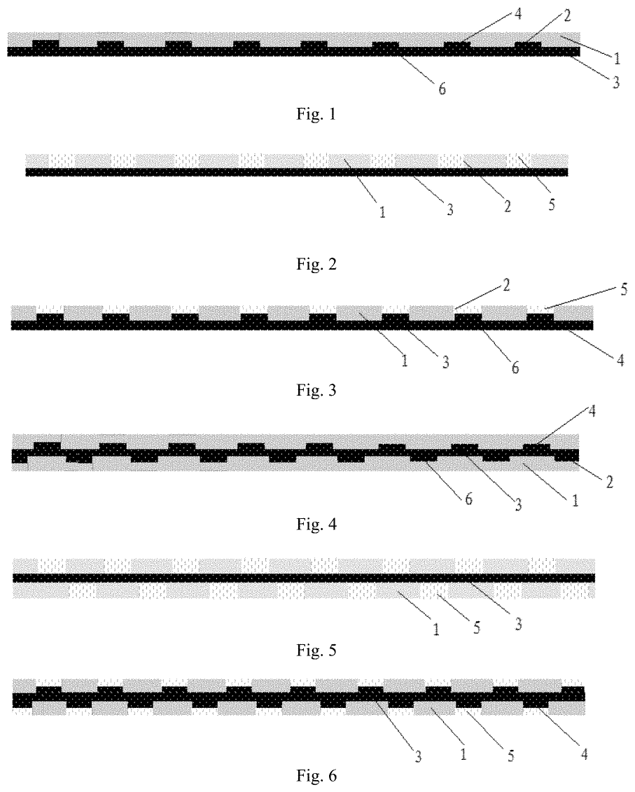

With reference to FIGS. 1-12, in a first aspect, the disclosure provides a support 7 for a flexible display module, the support comprises metal layers 1 and supporting layers 3 arranged with one above another, each metal layer 1 comprises non-patterned areas 12 and patterned areas 2, the patterned area 2 is a notch 4 and/or a micro-hole etching area 5 arranged on the metal layer 1, and a filling layer 6 is arranged in the notch 4. The supporting layers 3 are made of a polymer material, and the filling layers 6 are made of a polymer material, which is the same as or different from the material of the supporting layers 3.

Preferably, the patterned area 2 is strip-shaped, and at least one group of patterned area is arranged on the metal layer 1. The number of metal layers is greater than or equal to 2. When there are more than two metal layers 1, the supporting layers 3 are arranged between every two metal layers 1, and the materials of the metal layers 1 are the same or different. When there are more than two metal layers 1, the metal layers 1 are all provided with the patterned areas 2, the patterned areas 2 on two vertically adjacent metal layers are arranged in a staggered way, the adjacent patterned areas 2 have the same or different widths, and the patterned areas 2 on two vertically adjacent metal layers have the same or different shapes.

In practice, the metal layers 1 can be arranged differently according to the specific application, and several layers can be arranged as required. The patterned areas 2 can also be arranged differently according to the specific application, adjacent patterned areas 2 may have the same or different widths, and intervals between adjacent patterned areas 2 may be equal or unequal.

Based on different performance requirements (heat dissipation, low magnetism, low density and support performance), metal with different specifications may be adopted. There may be one or two metal layers 1, the supporting layer 3 is arranged between the two metal layers 1, and the materials of the two metal layers 1 are the same or different. The two metal layers 1 are both provided with patterned areas 2, the patterned areas 2 on two vertically adjacent metal layers are arranged in a staggered way, the adjacent patterned areas 2 have the same or different widths, and the patterned areas 2 on two vertically adjacent metal layers have the same or different shapes.

The adjacent patterned areas 2 have the same or different shapes, the patterned areas 2 may be notches 4 and/or micro-hole etching areas 5, or half of them are notches 4 and half are micro-hole etching areas 5, and the notches 4 are located on the sides close to the supporting layers 3.

In addition, the shapes of etched holes 11 in the micro-hole etching areas 5 are regular and/or irregular, including one or more of round, square or other irregular shapes. The lengths of the etched holes 11 are the same or different. The intervals between the etched holes 11 are the same or different.

In a second aspect, the disclosure provides a flexible display module, comprising a flexible display screen and the support 7 for the flexible display module as described above, and the support 7 is fixedly arranged on the display screen through an adhesive layer.

Further, the display screen comprises a flat area and a rolled-up area, the patterned areas 2 are arranged on the metal layers 1 corresponding to the rolled-up area, and at least one metal layer on the flat area is provided with a non-patterned area.

In a third aspect, the disclosure provides a display device comprising the support 7 for the flexible display module as described above.

The support 7 comprises at least one metal layer 1, a plurality of patterned areas 2 are arranged on the metal layers 1, supporting layers 3 are arranged under the metal layers 1, and notches 4 and/or micro-hole etching areas 5 are arranged on the patterned areas 2; and filling layers 6 are arranged in the notches 4, and the material of the filling layers 6 is the same as or different from that of the supporting layers 3.

As shown in FIG. 1, the support comprises one metal layer 1, the metal layer 1 is provided with notches 4, the metal layer is filled with polymer filling layers 6, and a supporting layer 3 is arranged under the metal layer. During processing, the supporting layer 3 is a polymer coating which fills the notches 4, so that the supporting layer 3 and the filling layers 6 are both obtained. The supporting layer 3 and the filling layers 6 should have high viscosity, low Tg point, low modulus and high resilience.

It should be noted that, in order to meet different application scenarios, the filling layers 6 and the supporting layer 3 can be made of the same or different materials. When they are made of different materials, according to requirements, the notches 4 are filled with a polymer material first, and then the supporting layer 3 is applied. The polymer material can be adhesive glue or other polymer materials with good resilience, such as silicone PU and foam glue.

As shown in FIG. 2, the support comprises one metal layer 1, the metal layer 1 is provided with micro-hole etching areas 5, and a supporting layer 3 is arranged under the metal layer 1.

As shown in FIG. 3, the support comprises one metal layer 1, and the metal layer 1 is provided with patterned areas 2, half of which are notches 4 and half are micro-hole etching areas 5. This solution is mainly used for metal pieces with thicknesses above 0.05. By conducting etching for thinning in different areas, the bending performance of the support 7 can be improved on the premise of ensuring the supporting performance of metal pieces. In addition, the lower polymer material layer has buffering, supporting and rebounding effects.

As shown in FIG. 4, the support comprises two metal layers 1, a supporting layer 3 is arranged between the two metal layers 1, and the materials of the two metal layers 1 are the same or different. It should be noted that because the support 7 is attached to the flexible display screen, the bending amplitudes of the upper and lower metal layers 1 are different due to the thickness. In order to meet different bending properties, the upper and lower metal layers 1 can be made of different metals, which can also meet different performance requirements (heat dissipation, low magnetism, low density and support performance). The thickness of the metal layers 1 ranges from 0.02 mm to 1 mm. The metal material is high strength stainless steel, titanium and other alloys, and can also include soft high-thermal/electric conductivity metals or alloys such as copper, silver, tin and aluminum.

In addition, the patterned areas 2 of the upper and lower metal layers 1 may be located at the same positions or arranged in a staggered manner, and the shapes of the patterned areas 2 may be the same or different. It should be noted that since the support 7 is attached to the flexible display screen, the bending amplitudes of the upper and lower metal layers 1 are different due to the thickness, and the patterned areas 2 can be staggered to meet different bending properties. The staggered arrangement can effectively release the bending strain, and can also ensure the supporting function and resilience of the support 7.

As shown in FIG. 4, the patterned areas 2 of the upper and lower layers are all notches 4 which are arranged in a staggered manner.

As shown in FIG. 5, the patterned areas 2 in the upper and lower layers are all micro-hole etching areas 5 which are arranged in a staggered manner.

As shown in FIG. 6, the patterned areas 2 of the upper and lower layers are half notches 4 and half micro-hole etching areas 5 which are arranged in a staggered manner. According to the solution, the bending performance of the support 7 can be further improved on the premise of ensuring the supporting performance of the metal pieces.

A flexible display module is provided with a support 7 for the flexible display module, the support 7 is fixedly arranged on a display screen through an adhesive layer 8, the display screen is a flexible display screen, and the display screen comprises a flat area 9 and a rolled-up area 10.

The adhesive layer and the polymer filling layers 6 should have high viscosity, low Tg point, low modulus and high resilience.

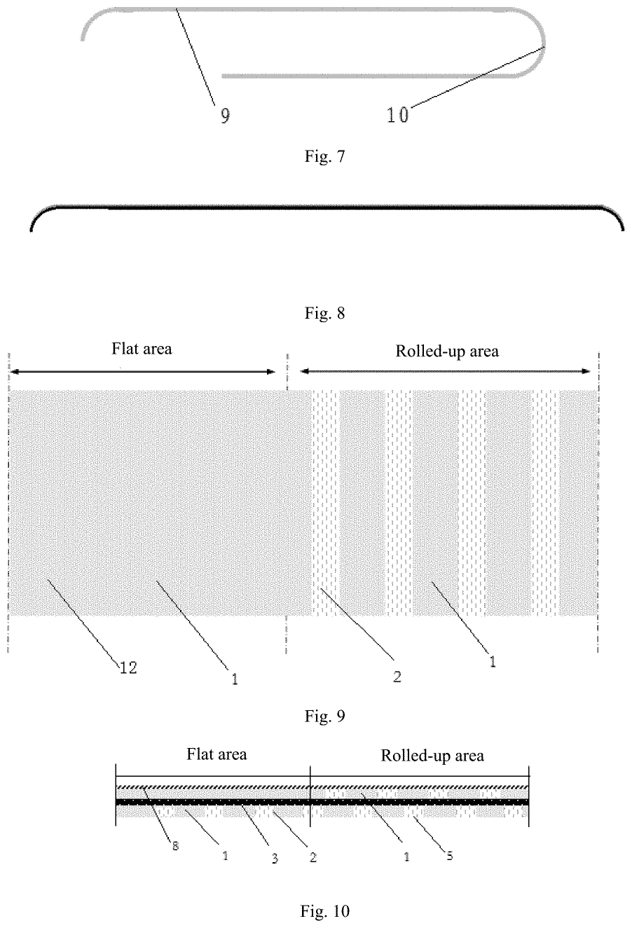

FIG. 7 shows a rolled state of the display module, and FIG. 8 shows a slide-rolled state of the display module. In practical, there may be one or two metal layers 1 on the support 7, and the two metal layers are fixedly connected through the supporting layer 3.

The patterned areas 2 are arranged in the rolled-up area, and there can be one or more groups of patterned areas 2 on each metal layer 1. As shown in FIGS. 9-10, the patterned areas 2 can be arranged differently according to the specific application, adjacent patterned areas 2 may have the same or different widths, and intervals between adjacent patterned areas 2 may be equal or unequal.

In order to meet different bending properties, the patterned areas 2 on the upper and lower metal layers are arranged in a staggered way, the widths of adjacent patterned areas 2 are the same or different, and the shapes of the patterned areas 2 on the upper and lower metal layers are the same or different.

The metal layers 1 are arranged in the flat area to support the display screen. When one metal layer 1 is provided, the metal layer 1 is a smooth metal layer 1 for the sake of better support, and no patterned area 2 is arranged on the metal layer. If two metal layers 1 are provided, patterned areas 2 may be arranged on one of the metal layers 1 to reduce the weight of the display module. Of course, the patterned area 2 may be etched or a blank filled with a polymer material.

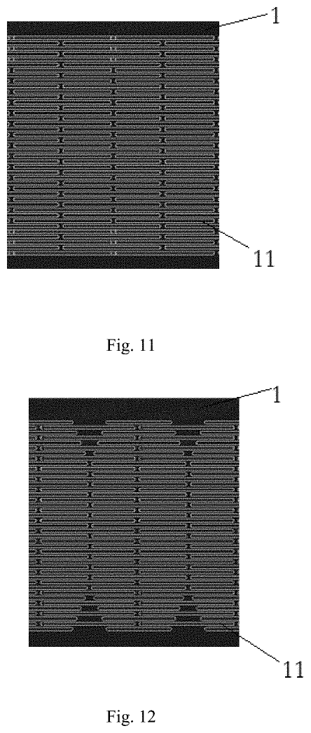

The lengths of the etched holes 1111 in the micro-hole etching area 5 are the same or different. The intervals between the etched holes 11 are the same or different. In order to suit different application scenarios or meet different bending properties, the internal stress is generally the largest in the bent area. In order to avoid fractures in the case of equally spaced etched holes 11, a progressive design can be adopted to avoid fatigue fractures while ensuring the bending ability. In addition, the progressive design of the etched holes 11 can also improve falling ball or pen impact resistance. FIG. 11 shows the design of etched holes 11 with equal spacing, and FIG. 12 shows a progressive design of etched holes 11.

To sum up, the technical solutions provided by the embodiments of the disclosure have the following beneficial effects:

The support provided by the embodiments of the disclosure adopts a single-layer or multi-layer metal lamination design with different materials, and is characterized by high strength, low magnetic permeability, thermal conductivity, resilience and the like; the metal layers are provided with the patterned areas which can be provided with different sizes, shapes and patterns to meet different rolling radii so as to suit different application scenarios; meanwhile, the upper and lower metal layers are designed with different patterns, which can realize inward bending or rolling; and the progressive design of the etched holes in the micro-hole etching areas improves the position with the greatest stress when the micro-hole etching areas and non-micro-hole etching areas are in contact with each other in the bent area, so as to improve falling ball or pen impact resistance.

It should be noted that the orientation or position relationship indicated by the terms “length”, “width”, “upper”, “lower”, “front”, “rear”, “left”, “right”, “vertical”, “horizontal”, “top”, “bottom”, “inner” and “outer” are based on the orientation or position relationship shown in the drawings, only for convenience of describing the disclosure and simplifying the description, and do not indicate or imply that the indicated device or element must have a specific orientation, or be constructed and operate in a specific orientation, and therefore cannot be understood as a limitation of the disclosure.

The terms “first” and “second” are only used for descriptive purposes, and cannot be understood as indicating or implying relative importance or implicitly indicating the number of indicated technical features. Therefore, the features defined with “first” and “second” may include one or more of the features explicitly or implicitly. In the description of the disclosure, unless otherwise specified, the meaning of “a plurality of” is two or more.

Unless otherwise defined, the technical and scientific terms used herein have the same meanings as commonly understood by those skilled in the technical field of this disclosure. Terms used herein are for the purpose of describing specific implementations only, and are not intended to limit the disclosure. Terms such as “arrange” used herein can mean that one component is directly attached to another component, or that one component is attached to another component through an intermediate piece. A feature described in one embodiment herein can be applied to another embodiment alone or in combination with other features, unless the feature is not applicable in the other embodiment or otherwise stated.

The disclosure has been explained by the above-mentioned embodiments, but it should be understood that the above-mentioned embodiments are only for the purpose of illustration and explanation, and are not intended to limit the disclosure. It can be understood by those skilled in the art that many more variations and modifications can be made according to the teachings of the disclosure, and all of these variations and modifications fall within the scope of the disclosure.

1. A support for a flexible display module, comprising metal layers and supporting layers arranged with one above another, wherein each metal layer comprises non-patterned areas and patterned areas, the patterned area is a notch and/or a micro-hole etching area arranged on the metal layer, and a filling layer is arranged in the notch.

2. The support for the flexible display module according to claim 1, wherein the patterned area is strip-shaped, and at least one group of the patterned area is arranged on the metal layer.

3. The support for the flexible display module according to claim 1, wherein the patterned area comprises the notch and the micro-hole etching area which are arranged with one above the other, and the notch is located on the side of the patterned area close to the supporting layer.

4. The support for the flexible display module according to claim 1, wherein the number of metal layers is greater than or equal to 2.

5. The support for the flexible display module according to claim 4, wherein under the case that there are two metal layers, the supporting layers are arranged between the two metal layers.

6. The support for the flexible display module according to claim 4, wherein under the case that there are two metal layers, the metal layers are all provided with the patterned areas, and the patterned areas on two vertically adjacent metal layers are arranged in a staggered way.

7. The support for the flexible display module according to claim 1, wherein the shapes of etched holes in the micro-hole etching areas include one or more of round, square or other irregular shapes.

8. The support for the flexible display module according to claim 1, wherein the supporting layers are made of a polymer material.

9. The support for the flexible display module according to claim 1, wherein the filling layers are made of a polymer material.

10. A flexible display module, comprising a flexible display screen and the support for the flexible display module according to claim 1, wherein the support is fixedly arranged on the flexible display screen through an adhesive layer.

11. The flexible display module according to claim 10, wherein the flexible display screen comprises a flat area and a rolled-up area, the patterned areas are arranged on the metal layers corresponding to the rolled-up area, and at least one metal layer on the flat area is provided with the non-patterned area.

12. A display device, wherein the display device comprises the support for the flexible display module according to claim 1.
